(19) United States
(12) Patent Application Publication
(10) Pub. No.: US 2015/0092170 A1
(43) Pub. Date: Apr. 2, 2015

(54) METHOD FOR REPAIRING OPTICAL ELEMENTS, AND OPTICAL ELEMENT

(71) Applicant: Carl Zeiss Laser Optics GmbH, Oberkochen (DE)

(72) Inventors: Oli Ehrler, Karlsruhe (DE); Uwe Meier, Beimerstetten (DE); Alexander Uhl, Oberkochen (DE); Holger Kierey, Aalen (DE)

(21) Appl. No.: 14/519,449

(22) Filed: Oct. 21, 2014

Related U.S. Application Data
(63) Continuation of application No. PCT/EP2013/001244, filed on Apr. 25, 2013.
(60) Provisional application No. 61/639,370, filed on Apr. 27, 2012.

(30) Foreign Application Priority Data
Apr. 27, 2012 (DE) 102012207141.5

(51) Int. Cl. G03F 7/20

(52) U.S. Cl. CPC G03F 7/708
USPC 355/55; 427/162; 216/24; 428/457; 428/448; 428/469; 428/472

(57) ABSTRACT

A method for repairing a collector for an EUV projection exposure apparatus having a first coating and a second coating, wherein the first coating is arranged between the second coating and a surface of the collector. The method includes completely or partly removing the first coating by treatment with a first chemical solution, and applying a new first coating.

### CROSS-REFERENCE TO RELATED APPLICATIONS

The present application is a continuation of, and claims benefit under 35 USC 120 to, international application PCT/EP2013/001244, filed Apr. 25, 2013, which claims benefit under 35 USC 119 of German Application No. 10 2012 207 141.5, filed Apr. 27, 2012. International application PCT/EP2013/001244 also claims priority under 35 USC 119(e) to U.S. Provisional Application No. 61/639,370, filed Apr. 27, 2012. The entire disclosure of international application PCT/EP2013/001244 is incorporated by reference herein.

The invention relates to a method for repairing a collector for an EUV projection exposure apparatus having a first coating and a second coating, wherein the first coating is arranged between the second coating and a surface of the collector. The method involves completely or partly removing the first coating by treatment with a first chemical solution, and subsequently applying a new first coating. The invention furthermore relates to a collector for a EUV projection exposure apparatus which is particularly suitable for carrying out the method.

Lithography methods are used for producing microelectronic components or other micro- or nanostructured elements. The associated projection exposure apparatuses are increasingly being operated at short wavelengths in order that a high resolution is ensured. By way of example, a radiation source can be provided which can generate radiation in the extreme ultraviolet wavelength range (EUV) having a wavelength of 13 nm.

Furthermore, the projection exposure apparatuses have optical units having a multiplicity of mirrors, including a collector which is arranged in proximity to the radiation source and which focuses and passes on the radiation from the EUV radiation source.

Optical elements used in EUV projection exposure apparatuses have to be able to withstand extreme conditions. Alongside high thermal loading and irradiation by the EUV radiation, they are often also subjected to loading resulting from impinging particles from the radiation source, whereby damage and contamination of the optically active layers of the optical elements can occur. If a plasma-based radiation sources is used in the EUV projection exposure apparatus, particulate or film-like deposits of the plasma material and/or the material used for plasma generation on the EUV-reflective layers of the optical elements and damage to the EUV-reflective layers resulting from impinging particles can occur, which lead to losses in reflectivity and ultimately require replacement of the optical elements.

In order to increase the effective lifetime of the optical elements, a final protective layer can be applied on the EUV-reflective layers of the optical elements, the protective layer protecting the optical layers against defects resulting from fast particles and ionizing radiation from the EUV radiation source. Deposits of the plasma material can be removed ex situ or in situ via plasma-based or wet-chemical etching processes. The fast particles formed in the radiation source and the ionizing radiation also lead, however, to damage to the protective layer, such that the latter is slowly eroded and/or locally damaged during operation. This has the consequence that the EUV-reflective layers are finally damaged after erosion of the protective layer, such that the optical element finally becomes unusable.

Since the corresponding optical elements such as mirrors and collector are manufactured with high outlay, it is advantageous to provide repair possibilities. A method for repairing an optical element of an EUV projection exposure apparatus is known from U.S. Pat. No. 7,561,247 B2. In this case, the optical element comprises an EUV-reflective layer composed of ruthenium and a protective layer on the ruthenium, the protective layer comprising boron B, carbon C, silicon Si or germanium Ge. In order to repair the optical element, the protective layer is brought into contact with hydrogen radicals and hydrocarbon radicals and eroded in this way. A new protective layer can subsequently be applied. What is disadvantageous about the method in U.S. Pat. No. 7,561,247 B1 is that the radicals have to be generated in a complex manner before the beginning of the repair.

One object of the present invention is to provide an alternative, simpler method for repairing a collector for an EUV projection exposure apparatus, and also to provide a collector for an EUV projection exposure apparatus which can be repaired simply, cost-effectively and reliably with the aid of the method.

The object is achieved via a method via for repairing an a collector for an EUV projection exposure apparatus having a first coating and a second coating, wherein the first coating is arranged between the second coating and a surface of the collector. The method comprises completely or partly removing the first coating by treatment with a first chemical solution, and applying a new first coating. The first chemical solution used is an agent which has a first etching rate in combination with the material of the first coating and a second etching rate in combination with the material of the second coating, wherein the first etching rate is greater than the second etching rate at least by a factor of 5. The object is also achieved by a collector for an EUV projection exposure apparatus having a first coating, which comprises a metal, a metal oxide, a semiconductor oxide, a semiconductor nitride or a combination thereof, and having a second coating, which comprises a plurality of alternately deposited plies of molybdenum and silicon or which comprises a layer made of ruthenium, palladium, platinum or gold, wherein the first coating is arranged between the second coating and a surface of the collector.

The method according to the invention is distinguished by the fact that the first chemical solution used is an agent which has a first etching rate in combination with the material of the first coating and a second etching rate in combination with the material of the second coating, wherein the first etching rate is greater than the second etching rate at least by a factor of 5. In this case, an etching rate should be understood to mean an etching erosion per unit time, that is to say the layer thickness of the coating material which is eroded per unit time upon contact with the first chemical solution perpendicularly to the surface. In this case, the magnitude of the etching rate is dependent on the coating material used and the chemical solution used. Different etching rates generally arise in the case of different coating materials and an identical chemical solution. In this case, the first coating and/or the second coating can also each be constructed from a plurality of different individual plies. In this case, the first etching rate should be understood to mean a possibly weighted average value of the individual etching rates that result from the combinations of the first chemical solution with the individual plies of the first coating. Analogously thereto, in this case the second etching rate is defined as a possibly weighted average value of the individual etching rates that result from the combinations of the first chemical solution with the individual plies of the second coating.

The mutually coordinated choice of the materials of the first coating, of the second coating and of the first chemical solution ensures that the first coating is eroded upon contact between the collector and the first chemical solution, without the occurrence of appreciable damage to the underlying second coating of the collector caused by the first chemical solution.

In one development of the invention, the first chemical solution used is an aqueous acid. Such a solution can be produced cost-effectively and can be handled in a simple manner.

Alcohols such as methanol, ethanol or propanol can be added to the aqueous acid. Furthermore, it is also possible to use dilute aqueous acids or mixtures of dilute aqueous acids and mixtures of dilute aqueous acids with alcohols, in the course of the use of which the etching rate is reduced such that the etching process proceeds more slowly and is better controllable.

In one development of the invention, the first chemical solution used is phosphoric acid H₃PO₄, hydrofluoric acid HF, nitric acid HNO₃, perchloric acid HClO₄, tetrafluoroboric acid HBF₄, formic acid HCOOH, acetic acid CH₃COOH, sulfuric acid H₂SO₄, hydrochloric acid HCl or a mixture of the acids. These acids can be produced in a simple manner and are readily processable on a large industrial scale.

In one development of the invention, prior to completely or partly removing the first coating, a second chemical solution is applied, which differs from the first chemical solution in terms of a substance composition and/or concentration. As a result, it is possible to pretreat the first coating with a different chemical solution. In particular, deposits which may have formed on the first coating during the operation of the collector can be processed, and in particular detached, with the aid of the second chemical solution.

In one development, the second chemical solution used is an aqueous acid. Such a solution can be produced cost-effectively and can be handled in a simple manner.

In one development, the second chemical solution used is phosphoric acid H₃PO₄, hydrofluoric acid HF, nitric acid HNO₃, perchloric acid HClO₄, tetrafluoroboric acid HBF₄, formic acid HCOOH, acetic acid CH₃COOH, sulfuric acid H₂SO₄, hydrochloric acid HCl or a mixture of the acids. These acids can be produced in a simple manner and are readily processable on a large industrial scale. Furthermore, the same acids are thus available which, in a different concentration, are also used for processing the first coating, such that the number of acids required for carrying out the repair can be reduced or kept small.

In one development of the invention, prior to applying the new first coating, the collector is treated or cleaned with a solvent. In this way, it is possible to remove residues of the first chemical solution, of the second chemical solution and/or of the dissolved constituents of the second coating and, if appropriate, of the deposits formerly present on the second coating.

A collector for an EUV projection exposure apparatus according to the invention comprises a first coating, which comprises a metal, a metal oxide, a semiconductor oxide, a semiconductor nitride or a combination thereof, and a second coating, which comprises a plurality of alternately deposited plies of molybdenum and silicon. The first coating is arranged between the second coating and a surface of the collector. In this case, the surface should be understood to mean that surface of the collector which faces the incident radiation during operation. The first coating can itself form the surface of the collector. Without restricting generality, however, even further coatings can be arranged between the first coating and the surface of the collector. The second coating can also contain, alongside the plies of molybdenum and silicon, further plies of non-metals or other metals or other semiconductors, the thickness of which is less than the thickness of the plies of molybdenum or silicon and the function of which is to separate the plies of silicon and molybdenum. The second coating can also contain ruthenium, palladium, platinum or another noble metal.

The collector according to the invention has a material combination for which it is possible particularly simply to find a chemical solution which has a significantly higher etching rate in combination with the materials of the first coating than in combination with the materials of the second coating. In particular, the first coating can contain silicon nitride SiₓN_{y}, zirconium nitride ZrₓN_{y}, titanium oxide TiₓO, yttrium oxide YₓO_{y} or a combination thereof

In one development of the invention, a third coating composed of titanium nitride, titanium oxide, silicon nitride or silicon oxide is arranged between the first coating and the second coating. This results in a layer which has a particularly low etching rate in combination with many customary chemical solutions, in particular in comparison with the stated materials of the first coating and of the second coating.

Further advantages, characteristics and features of the present invention will become clear in the course of the following detailed description of exemplary embodiments with reference to the accompanying drawings.

In this case, specifically in the figures:

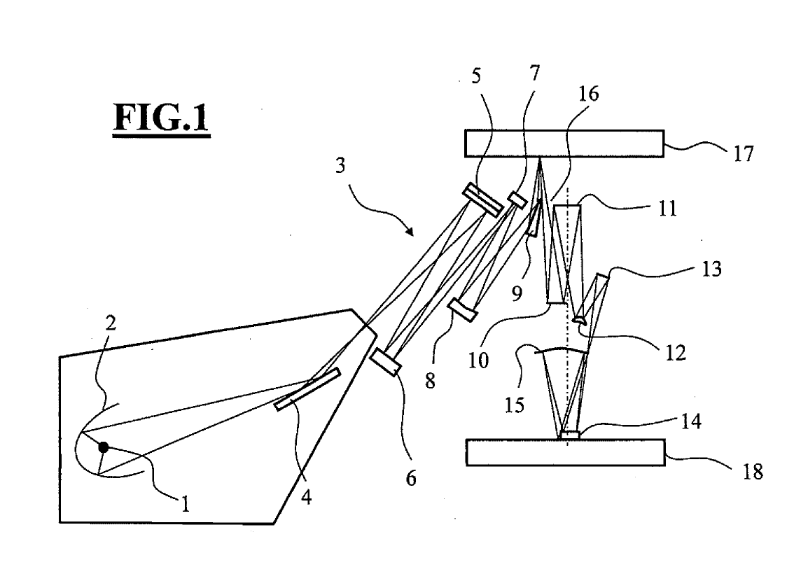

FIG. 1 shows an illustration of an EUV projection exposure apparatus in which the present invention can be used;

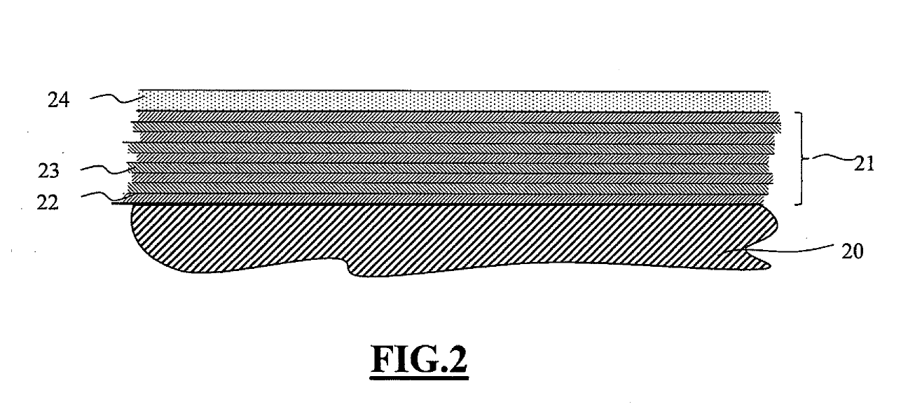

FIG. 2 shows a first exemplary embodiment of a collector according to the invention;

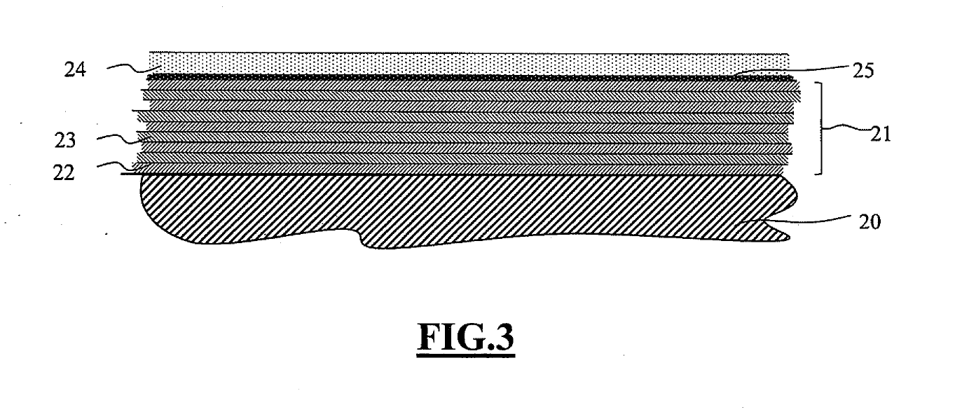

FIG. 3 shows a second exemplary embodiment of a collector according to the invention;

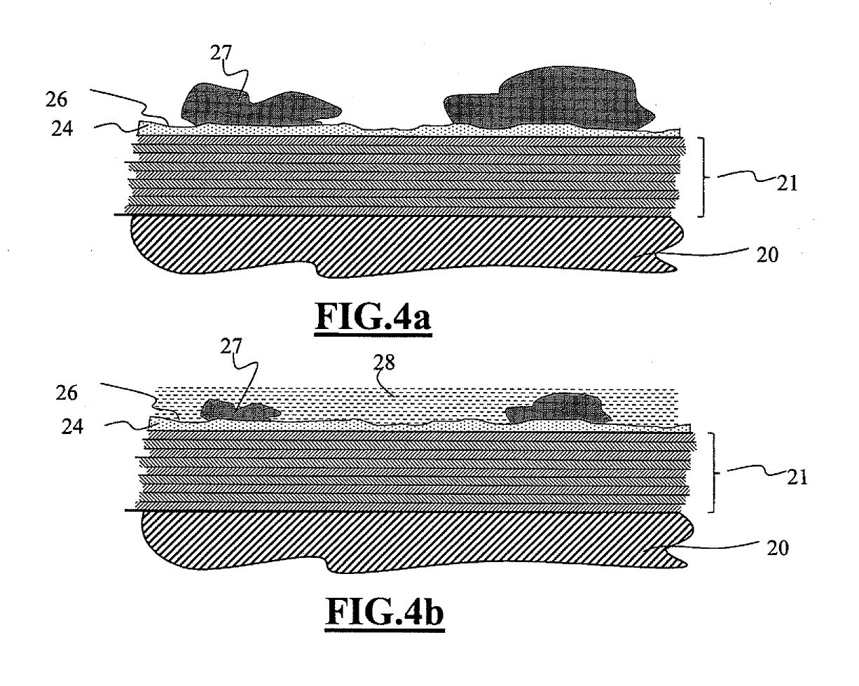

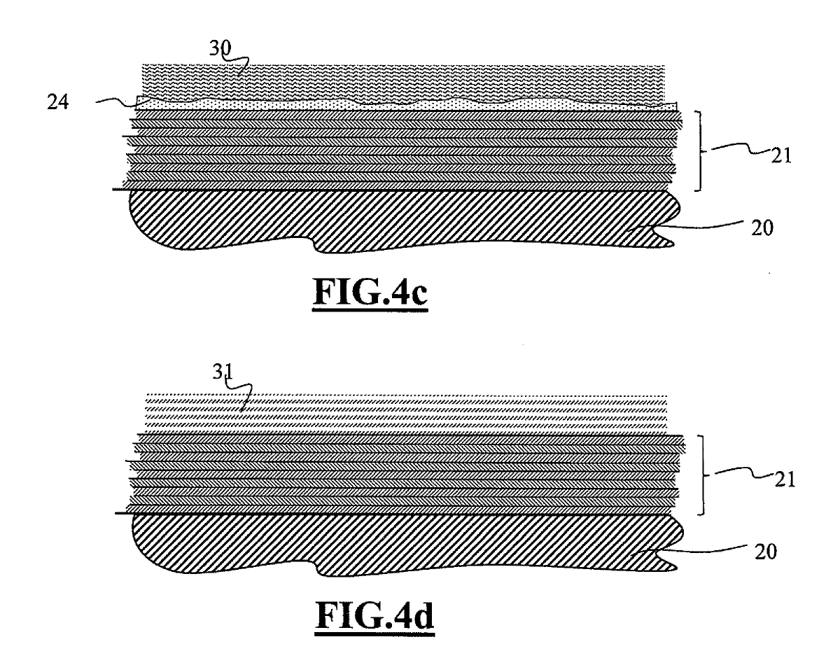

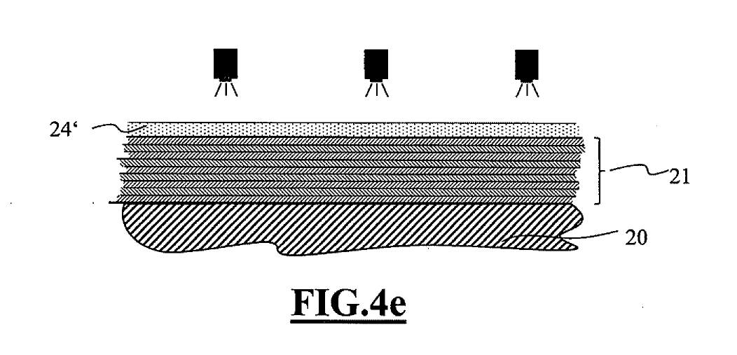

FIGS. 4a to 4e show a schematic illustration of the method steps;

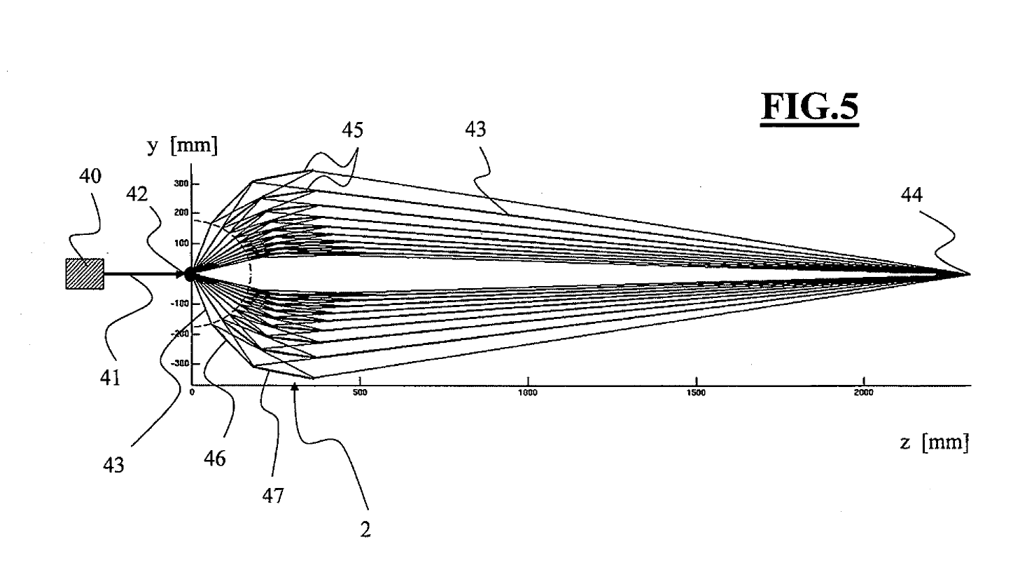

FIG. 5 shows a schematic illustration of a grazing incidence collector.

FIG. 1 shows an EUV projection exposure apparatus in a purely schematic illustration. Such a projection exposure apparatus comprises a radiation source 1 for generating a radiation in the extreme ultraviolet (EUV) range and a collector 2 for focusing and passing on the electromagnetic radiation emitted by the radiation source 1. An illumination system 3 comprises a plurality of optical elements in the form of mirrors. Via the mirrors 4 to 9, the EUV radiation 16 can be deflected onto a reticle 17, which has a structure to be imaged onto a wafer 18. The imaging is effected via a projection optical unit, which in turn comprises a plurality of optical elements in the form of mirrors 10 to 15. The mirrors 4 to 15 and the collector 2 have first coatings in the form of reflection coatings which are constructed from a multiplicity of thin layers and form a Bragg reflector.

FIG. 5 shows an alternative embodiment of a collector 2 for an EUV projection exposure apparatus. In this case the collector is embodied as a so called “grazing incidence” collector. In FIG. 5, a lens section of the grazing incidence collector 2 is shown. FIG. 5 furthermore shows a laser 40 for generating a laser beam 41 of a defined wave length. The laser beam 41 is directed on a target material 42, for example a tin droplet. Thus, the tin droplet is heated up and converted to a plasma state, and electromagnetic radiation 43 is emitted. The collector 2 projects an image of the plasma light source onto an intermediate focus 44.

In this exemplary embodiment, the collector 2 consists of nine mirror shells 45 which are arranged with rotational symmetry around a common collector axis. Each of the mirror shells 45 consists of two aspherical mirror segments, which are arranged so that they follow each other in the direction of the light. The first mirror segments 46, which are arranged closer to the target material 42, have the shape of a section of a hyperboloid, while the second mirror segments 47, which are arranged closer to the intermediate focus 44, have the shape of a section of an ellipsoid. Without restricting generality, a grazing incidence collector according to this invention may also be carried out with more mirror shells as nine or with less.

The present invention applies to normal incidence collectors (as shown in FIG. 1) as well as to grazing incidence collectors (as shown in FIG. 5).

The collector 2, arranged in direct proximity to the radiation source 1, is subjected to high thermal loading and also, alongside the radiation loading, to possible bombardment of particles from the radiation source 1, such that the coatings arranged on the surface of the collector can incur damage.

A plasma source is often used as the radiation source 1 in EUV lithography. In one exemplary embodiment, a tin droplet therein is abruptly evaporated by bombardment with a laser beam and converted to a plasma, thus giving rise to an electromagnetic radiation in the EUV wavelength range. In the case of such radiation sources, there is the risk of particulate or film-like deposits of tin being formed on the surface of the collector 2, which reduce the reflectivity of the collector 2 and thus the efficiency of the EUV projection exposure apparatus.

After damage and/or contamination of the reflection coating, the optical elements of the projection exposure apparatus have to be replaced, which is associated with a high complexity and with high costs since high demands in respect of dimensional accuracy and roughness of the surfaces have to be placed on the mirrors 4 to 15 and in particular also on the collector 2 of the EUV projection exposure apparatus. Accordingly, it is advantageous if the collector 2 and the mirrors 4 to 15 are configured in such a way that they can be easily restored in the event of damage and/or contamination.

FIG. 2 illustrates a first exemplary embodiment of an optical element that fulfils the demands mentioned above. The optical element is a mirror or a collector of an EUV projection exposure apparatus. Arranged on a substrate 20 is a second coating in the form of an EUV-reflective layer 21 formed from alternately deposited plies of molybdenum 22 and silicon 23. This construction has a particularly high reflectivity for EUV radiation.

In order to protect the EUV-reflective layer 21, a first coating in the form of a protective layer 24 is applied thereabove. The protective layer should (in particular in the case of use on the collector 2) generally have a low affinity for the plasma material of the radiation source and/or the material used for plasma generation (for example tin), in order largely to prevent deposits of the plasma material and/or the material used for plasma generation on the mirror or collector 2. Furthermore, the protective layer 24 is intended to have a high mechanical stability and to protect the underlying EUV-reflective layer 21 in particular against defects resulting from the fast particles and ionizing radiation formed during the use of the EUV radiation source. The protective layer is furthermore intended to have a high transmittance for the EUV radiation.

In the present exemplary embodiment, the protective layer 24 is embodied as a thin layer composed of a metal, a metal oxide, a semiconductor oxide, a semiconductor nitride or a combination of these materials. The protective layer 24 preferably comprises silicon nitride SiₓN_{y}, zirconium nitride ZrₓN_{y}, titanium oxide TiₓO_{y} or yttrium oxide YₓO_{y} with varying stoichiometry, or a combination of the materials mentioned. With these materials it is possible to realize a first coating having properties that can be optimally adapted to the demands of the respective application.

The use of molybdenum and silicon for the EUV-reflective layer 21 and a metal, metal oxide, semiconductor oxide, semiconductor nitride or a combination thereof for the protective layer 24 furthermore has the particular advantage that, for this material combination, chemical solutions exist which have a high etching rate with respect to the material of the protective layer 24 but a significantly lower etching rate with respect to the material of the EUV-reflective layer 21. As a result, with this material combination, the protective layer 24 can be removed particularly simply by applying a corresponding chemical solution in conjunction with at most little damage to the underlying EUV-reflective layer 21.

FIG. 3 illustrates a second exemplary embodiment of an optical element according to the invention. The second exemplary embodiment differs from the exemplary embodiment in accordance with FIG. 2 in that a third coating in the form of a stop layer 25 is arranged between the EUV-reflective layer 21 and the protective layer 24. In this exemplary embodiment, the stop layer 25 comprises titanium nitride, titanium oxide, silicon nitride or silicon oxide or some other material that has a particularly low etching rate in combination with the chemical solution for removing the protective layer. The etching rate with which material of the third coating is removed when a chemical solution (in particular one of the chemical solutions mentioned in the following explanation of FIG. 4) acts on the third coating can be lower for example by a factor of more than 10, in particular more than 100, more particularly also more than 100, than the etching rate with which material of the first coating is removed when the same chemical solution acts on the first coating. The stop layer 25 at least largely prevents contact between the chemical solution and the EUV-reflective layer 21, thereby preventing erosion of the EUV-reflective layer 21 during the repair of the optical element.

A method according to the invention is explained in greater detail below with reference to FIGS. 4a to 4e.

FIG. 4a illustrates a section through a surface structure of a mirror or collector of an EUV projection exposure apparatus. As a result of the high thermal loading and the radiation loading from the EUV radiation source 1, defects have arisen on the protective layer 24, such that the protective layer has a rough and uneven surface. Thereabove, during operation, deposits 27 of the plasma material, in this case tin deposits, have arisen on the surface of the protective layer, which impair the quality of the optical element. The tin deposits are illustrated merely schematically. Deposits on optical elements of the EUV projection exposure apparatus are often also embodied as a film.

During further operation of the optical element of the EUV projection exposure apparatus shown in FIG. 4a, there is the risk of the protective layer 24 being eroded further until the underlying EUV-reflective layer is also damaged by fast particles and/or ionizing radiation from the radiation source. In order to avoid this, repair of the optical element is necessary.

In order to repair the mirror or collector, it is optionally possible, as illustrated in FIG. 4b, firstly to apply a second chemical solution 28 as reagent for dissolving the tin deposits to the optical element. The second chemical solution 28 is preferably embodied as an aqueous acid and comprises phosphoric acid H₃PO₄, hydrofluoric acid HF, nitric acid HNO₃, perchloric acid HClO₄, tetrafluoroboric acid HBF₄, formic acid HCOOH, acetic acid CH₃COOH, sulfuric acid H₂SO₄, hydrochloric acid HCl or a mixture of the acids in a concentration which has a high etching rate in combination with the material of the plasma deposits and a low etching rate in combination with the material of the protective layer 24. The etching rate in combination with the material of the deposits 27 is preferably greater than the etching rate of the second chemical solution 28 in combination with the material of the protective layer 24 by a factor of greater than 5, with further preference by a factor of greater than 10, with further preference by a factor of greater than 100, and with further preference by a factor of greater than 1000. With the aid of the second chemical solution, the deposits are at least largely removed, without the occurrence of appreciable further damage to the protective layer 24.

After the deposits 24 have been removed, the second chemical solution 28 is removed. Optionally, the mirror or collector can be purged with a solvent in order to remove residues of the second chemical solution 28 and/or dissolved residues of the deposits 27 and/or reaction products.

Subsequently, as illustrated in FIG. 4c, a first chemical solution 30 is applied to the protective layer 24, which has a first etching rate in combination with the material of the protective layer 24 and a second etching rate in combination with the material of the

EUV-reflective layer, wherein the first etching rate is greater than the second etching rate at least by a factor of 5, preferably greater at least by a factor of 10, with further preference greater by a factor of 100, with further preference also greater by a factor of 1000. The first chemical solution and the materials of the EUV-reflective layer 21 and of the protective layer 24 are coordinated with one another in such a way that contact between the first chemical solution 30 and the optical element leads to erosion of the protective layer 24, without the underlying EUV-reflective layer 21 being appreciably damaged by the first chemical solution 30. In this exemplary embodiment, the first chemical solution 30 used is an aqueous acid, for example phosphoric acid H₃PO₄, hydrofluoric acid HF, nitric acid HNO₃, perchloric acid HClO₄, tetrafluoroboric acid HBF₄, formic acid HCOOH, acetic acid CH₃COOH, sulfuric acid H₂SO₄, hydrochloric acid HCl or a mixture of the acids. In an alternative exemplary embodiment, the first chemical solution used is a dilute aqueous acid or mixtures of dilute aqueous acids and mixtures of dilute aqueous acids with alcohols. In this case, the etching process takes place more slowly, thereby enabling better control of the process sequence.

After the removal of the protective layer 24, the first chemical solution 30 is removed. In an optional method step, as illustrated in FIG. 4d, a further solvent 31 can then be applied to the optical element in order to remove residues of the first chemical solution 30 and/or dissolved residues of the protective layer 24 and/or reaction products.

Subsequently, in a further method step, a new protective layer 24′ is applied to the EUV-reflective layer 21 for example by physical or chemical deposition.

In a further exemplary embodiment (not illustrated), the substrate of the mirror or collector is covered prior to treatment with the first and/or second chemical solution, or the mirror or collector is mounted in a receptacle device which prevents the substrate itself from coming into contact with the reagents. Damage to the substrate as a result of contact with the first chemical solution and/or the second chemical solution is avoided as a result.

The invention has been explained on the basis of exemplary embodiments in which the second coating is arranged directly on a substrate and the first coating is arranged directly on the surface of the optical element. Without restricting generality, even further coatings can be present between the substrate and the second coating, and between the first coating and the surface of the optical element. What is essential to the invention is that the first coating, the second coating adjoining the first coating and the chemical solution (reagent) are chosen such that the etching rates of the combinations of chemical solution first coating and chemical solution second coating differ so distinctly that, after possible complete or partial erosion of the first coating, erosion of the second coating is slowed down, such that damage to the second coating owing to contact with the chemical solution is limited to a minimum. That means that possible damage to the second coating owing to contact with the chemical solution is intended to be so small that the optical quality of the optical element, that is to say the reflectivity, for example, is impaired insignificantly at most.

In the exemplary embodiments, the invention has been explained on the basis of reflective optical elements from EUV lithography. Without restricting generality, however, the invention can also be applied to other optical elements, in particular to refractive optical elements such as lens elements, prisms or diffractive optical elements such as gratings of diffractive elements for forming beams or the like. Likewise, the invention is not restricted to applications in EUV lithography.

1-11. (canceled)

12. A method of modifying an EUV projection exposure collector which comprises a first coating and a second coating, the first coating being between the second coating and a surface of the collector, the method comprising:
a) using a first chemical solution to at least partially remove the first coating; and
b) applying a third coating to at least partially replace the removed first coating,
wherein:
the first coating comprising a first material comprising at least one material selected from the group consisting of nitride SiₓN_{y}, zirconium nitride ZrₓN_{y}, titanium oxide TiₓO, and yttrium oxide YₓO_{y};
the second coating comprising a second material,
the first chemical solution has a first etching rate for the first material;
the first chemical solution has a second etching rate for the second material; and
the first etching rate is at least five times greater than the second etching rate.

13. The method of claim 12, wherein a) comprises completely removing the first coating.

14. The method of claim 12, wherein the first chemical solution comprises an aqueous acid.

15. The method as claimed in claim 12, wherein the first chemical solution comprises at least one acid selected from the group consisting of phosphoric acid H₃PO₄, hydrofluoric acid HF, nitric acid HNO₃, perchloric acid HClO₄, tetrafluoroboric acid HBF₄, formic acid HCOOH, acetic acid CH₃COOH, sulfuric acid H₂SO₄, and hydrochloric acid HCl.

16. The method of claim 12, further comprising, prior to a), applying a second chemical solution which is different from the first chemical solution.

17. The method of claim 16, wherein the second chemical solution comprises a different substance composition from the first chemical solution.

18. The method of claim 16, wherein the second chemical solution comprises a concentration of components which is different from the first chemical solution.

19. The method of claim 16, wherein the second chemical solution comprises an aqueous acid.

20. The method of claim 16, wherein the second chemical solution comprises at least one acid selected from the group consisting of phosphoric acid H₃PO₄, hydrofluoric acid HF, nitric acid HNO₃, perchloric acid HClO₄, tetrafluoroboric acid HBF₄, formic acid HCOOH, acetic acid CH₃COOH, sulfuric acid H₂SO₄, and hydrochloric acid HCl.

21. The method of claim 12, wherein, prior to b), the collector is treated with a solvent.

22. The method of claim 12, wherein the second coating comprises a plurality of alternately layers of molybdenum and silicon.

23. The method of claim 12, wherein the second coating comprises a layer comprising ruthenium, palladium, platinum or gold.

24. The method of claim 12, wherein the third coating comprises titanium nitride, titanium oxide, silicon nitride or silicon oxide.

25. A collector comprising a first coating and a second coating, wherein:
the first coating is between the second coating and a surface of the collector;
the first coating comprises at least one material comprising at least one material selected from the group consisting of nitride SiₓN_{y}, zirconium nitride ZrₓN_{y}, titanium oxide TiₓO, and yttrium oxide YₓO_{y};
the second coating comprises: a) a plurality of alternately layers of molybdenum and silicon; or b) a layer comprising ruthenium, palladium, platinum or gold; and
the collector is an EUV projection exposure collector.

26. The collector of claim 25, wherein the second coating comprises a plurality of alternately layers of molybdenum and silicon.

27. The collector of claim 25, wherein the second coating comprises a layer comprising ruthenium, palladium, platinum or gold.

28. The collector of claim 25, further comprising a third coating between the first and second coatings, wherein the third coating comprises titanium nitride, titanium oxide, silicon nitride or silicon oxide.

29. The collector of claim 25, wherein the collector is a grazing incidence collector.

30. An apparatus, comprising:
a collector according to claim 25;
an illumination system configured to illuminate a reticle; and
a projection optical unit configured to project an image of the reticle onto a wafer.

31. A method, comprising:
providing an apparatus which comprises a collector according to claim 25, an illumination system and a projection optical unit;
using the illumination system to illuminate a reticle; and
using the projection optical unit to project at least a portion of the illuminated reticle onto a wafer.
